(19) United States
(12) Patent Application Publication
(10) Pub. No.: US 2023/0197447 A1
(43) Pub. Date: Jun. 22, 2023

(54) METHOD AND APPARATUS FOR FORMING CRYSTALLINE SILICON FILM

(71) Applicant: Tokyo Electron Limited, Tokyo (JP)

(72) Inventors: Kota UMEZAWA, Nirasaki City (JP); Yoshimasa WATANABE, Nirasaki City (JP)

(21) Appl. No.: 18/084,908

(22) Filed: Dec. 20, 2022

(30) Foreign Application Priority Data
Dec. 21, 2021 (JP) 2021-206922
Nov. 14, 2022 (JP) 2022-181677

(51) Int. Cl. H01L 21/02; H01L 21/3065; C23C 16/24; C23C 16/56; C30B 1/02; C30B 29/06

(52) U.S. Cl. CPC H01L 21/02675; H01L 21/02532; H01L 21/02592; H01L 21/3065; C23C 16/24; C23C 16/56; C30B 1/023; C30B 29/06

(57) ABSTRACT

A method of forming a crystalline silicon film includes forming a first amorphous silicon film on a substrate, forming a crystal nucleation film in which crystal nuclei of silicon are formed by performing a first annealing on the substrate having the first amorphous silicon film formed thereon, performing etching with an etching gas, forming a second amorphous silicon film on the crystal nuclei remaining after the etching, and forming a crystalline silicon film by performing a second annealing on the substrate after the forming of the second amorphous silicon film to grow the crystal nuclei.

### CROSS-REFERENCE TO RELATED APPLICATIONS

This application is based upon and claims the benefit of priority from Japanese Patent Application Nos. 2021-206922 and 2022-181677, filed on Dec. 21, 2021 and Nov. 14, 2022, respectively, the entire contents of which are incorporated herein by reference.

### TECHNICAL FIELD

The present disclosure relates to a method and apparatus for forming a crystalline silicon film.

### BACKGROUND

Crystalline silicon films are used, for example, as channels in semiconductor devices. From the viewpoint of suppressing an increase in channel resistance due to scattering of carriers at crystal grain boundaries, etc., there is a trend toward increasing grain sizes.

As a technique for forming a crystalline silicon film having a large grain size, Patent Document 1 has proposed a method in which, on a first amorphous silicon film in which crystals grow slowly, a second amorphous silicon film in which crystals grow faster than those of the first amorphous silicon film is laminated and then crystallization treatment is performed.

### PRIOR ART DOCUMENT

### Patent Document

Patent Document 1: Japanese Laid-Open Publication No. 2015-115435

### SUMMARY

According to one embodiment of the present disclosure, there is provided a method of forming a crystalline silicon film including forming a first amorphous silicon film on a substrate, forming a crystal nucleation film in which crystal nuclei of silicon are formed by performing a first annealing on the substrate having the first amorphous silicon film formed thereon, performing etching with an etching gas, forming a second amorphous silicon film on the crystal nuclei remaining after the etching, and forming a crystalline silicon film by performing a second annealing on the substrate after the forming of the second amorphous silicon film to grow the crystal nuclei.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a first embodiment of a crystalline silicon film forming method.

FIG. 2 is a cross-sectional view illustrating an example of a substrate.

FIG. 3 is a cross-sectional view schematically illustrating the state in which an example of step ST1 in the first embodiment is performed.

FIG. 4 is a cross-sectional view schematically illustrating the state in which an example of step ST2 in the first embodiment is performed.

FIG. 5 is a cross-sectional view schematically illustrating the state in which an example of step ST3 in the first embodiment is performed.

FIG. 6 is a cross-sectional view schematically illustrating the state in which an example of step ST4 in the first embodiment is performed.

FIG. 7 is a cross-sectional view schematically illustrating the state in which an example of step ST5 in the first embodiment is performed.

FIG. 8 is a cross-sectional view schematically illustrating the process of forming a second amorphous silicon film and growing the second amorphous silicon film by solid-phase epitaxial growth in the state in which fine crystal grains and an amorphous portion are present.

FIG. 9 is a cross-sectional view schematically illustrating the state in which a crystalline silicon film is formed from the state of FIG. 8.

FIG. 10 is an EBSD analysis image showing the state of crystal grains in a crystalline silicon film obtained by an experimental example of the first embodiment.

FIG. 11 is a flowchart illustrating a second embodiment of the crystalline silicon film forming method.

FIG. 12 is a cross-sectional view illustrating the state in which a first annealing by a laser in step ST6 is performed in the second embodiment.

FIGS. 13A and 13B are views illustrating examples of the shapes of laser irradiation regions in a first amorphous silicon film.

FIG. 14 is a cross-sectional view schematically illustrating the state in which an example of step ST3 in the second embodiment is performed.

FIG. 15 is a cross-sectional view schematically illustrating the state in which an example of step ST4 in the second embodiment is performed.

FIG. 16 is a cross-sectional view schematically illustrating the state in which an example of step ST5 in the second embodiment is performed.

FIG. 17 is an EBSD analysis image showing the state of crystal nuclei in an irradiation region when performing the first annealing by laser irradiation in the second embodiment.

FIG. 18 is a flowchart illustrating a third embodiment of the crystalline silicon film forming method.

FIG. 19 is an EBSD analysis image showing, in comparison, the states of crystal grains of a crystalline silicon film obtained by an experimental example of the first embodiment and a crystalline silicon film obtained by an experimental example of the third embodiment.

FIG. 20 is a vertical cross-sectional view illustrating an example of a processing apparatus capable of implementing the crystalline silicon film forming method according to an embodiment.

FIG. 21 is a horizontal cross-sectional view illustrating the processing apparatus of FIG. 20.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments will be described with reference to the accompanying drawings.

### First Embodiment

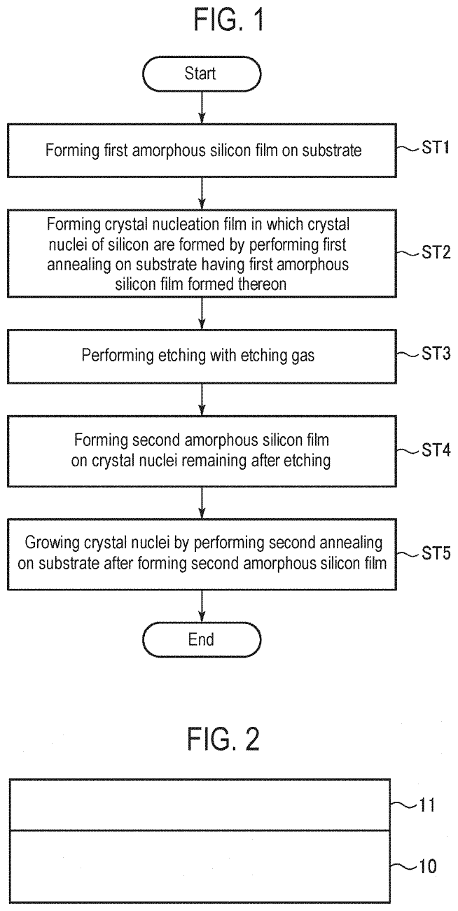

First, a first embodiment of a crystalline silicon film forming method will be described. FIG. 1 is a flowchart illustrating the first embodiment of the crystalline silicon film forming method. FIG. 2 is a cross-sectional view illustrating a substrate used in the first embodiment, and FIGS. 3 to 7 are cross-sectional views schematically illustrating the states in which examples of respective steps of the first embodiment are executed.

In this embodiment, first, a first amorphous silicon film is formed on the substrate (step ST1). Next, the substrate on which the first amorphous silicon film is formed is subjected to a first annealing to form a crystal nucleation film in which crystal nuclei of silicon are formed (step ST2). Next, etching is performed by using an etching gas (step ST3). Next, a second amorphous silicon film is formed on the crystal nuclei remaining after etching (step ST4). Next, by performing a second annealing on the substrate on which the second amorphous silicon film has been formed, the crystal nuclei are grown (step ST5).

Although not particularly limited, the substrate may be, for example, a substrate in which an underlayer film 11 is formed on a base body 10 as illustrated in FIG. 2. The substrate may be a semiconductor substrate (wafer) in which the base body 10 is a semiconductor, for example, a semiconductor base body which is a silicon base body, and the underlayer film 11 may be, for example, an insulating film such as an SiO₂ film or a SiN film.

In step ST1, a first amorphous silicon film 12 is formed on the underlayer film 11, for example, as illustrated in FIG. 3. The first amorphous silicon film 12 is for generating crystal nuclei of silicon. The first amorphous silicon film 12 is formed by a CVD method using a silicon (Si) source gas.

As the Si source gas for forming the first amorphous silicon film 12, all Si-containing compounds applicable to the CVD method may be used without particular limitation, but silane-based compounds and aminosilane-based compounds may be preferably used. The silane-based compounds may be, for example, monosilane (SiH₄), disilane (Si₂H₆), and the like, and the aminosilane-based compounds may be, for example, butyl aminosilane (BAS), bis-tertiary butyl aminosilane (BTBAS), dimethylaminosilane (DMAS), bisdimethylaminosilane (BDMAS), and the like. Since it is desirable to reduce the formation density of crystal nuclei, it is preferable to use, for example, disilane or a higher-order silane equal to or higher than disilane.

The specific process conditions at this time vary depending on the Si source gas, but the temperature of the substrate of 200 to 600 degrees C. and the pressure of about 0.1 to 100 Torr (13 to 13,000 Pa) may be used. As a specific example, when Si₂H₆ gas is used as the Si source gas, the temperature of the substrate is 350 to 500 degrees C., for example, 425 degrees C., and the pressure is 0.1 to 10 Torr (13 to 1,300 Pa), for example, 0.45 Torr (60 Pa).

The thickness of the first amorphous silicon film 12 is sufficient as long as silicon crystal nuclei can be effectively generated, and may be 50 nm or less. Preferably, the thickness is 1 to 15 nm, for example 10 nm.

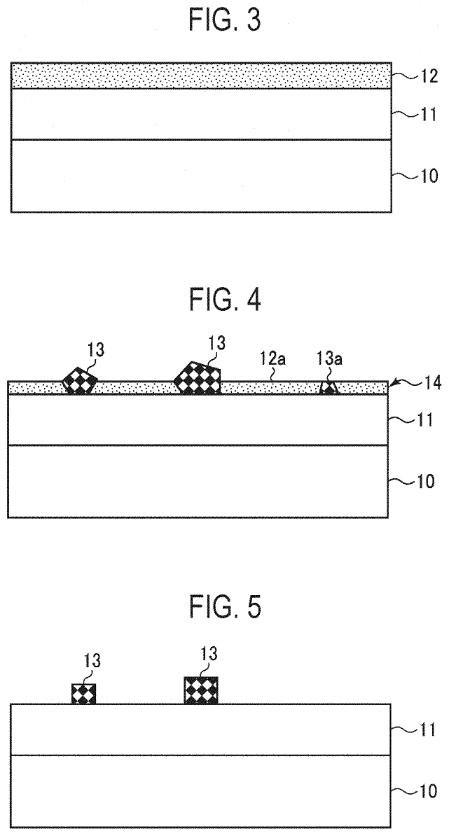

In step ST2, by performing a first annealing, for example, as illustrated in FIG. 4, crystal nuclei 13 of silicon are generated from the first amorphous silicon film 12 to form a crystal nucleation film 14 having crystal nuclei 13 formed therein. 12a denotes an amorphous portion, and 13a denotes fine crystal nuclei.

The first annealing in step ST2 may be performed by a heat treatment. When the first annealing is performed by a heat treatment, the entire first amorphous silicon film 12 is annealed, and the entire first amorphous silicon film 12 is turned into the crystal nucleation film 14 illustrated in FIG. 4. When the first annealing is performed by a heat treatment, the temperature of the substrate may be any temperature at which silicon crystal nuclei 13 are generated, and is preferably equal to or higher than the temperature at which the first amorphous silicon film 12 is formed. As the distance between crystal nuclei to be formed increases, crystalline silicon having a larger grain size can be formed. Therefore, in order to form crystalline silicon having a larger grain size, it is more preferable to set the temperature of the first annealing to a temperature at which silicon migrates. In order to cause migration, it is preferable to set the annealing temperature to 800 degrees C. or higher, and it is more preferable to set the annealing temperature to 900 degrees C. or higher. The upper limit of the annealing temperature is the melting temperature of silicon, but in practice the highest temperature that can be used for the apparatus is the upper limit.

The atmosphere when the first annealing in step ST2 is performed by a heat treatment may be a vacuum atmosphere, an inert gas atmosphere, or a H₂ gas atmosphere. The vacuum atmosphere may be formed, for example, by switching the vacuum pump (an exhaust device) into an evacuation state in the state in which no gas is supplied into the processing container in which the annealing process is performed, or in the state in which a small amount of gas is supplied into the processing container. When the first annealing is performed at a high temperature of 800 degrees C. or higher to cause migration of silicon, the vacuum atmosphere is preferable. When a gas such as an H₂ gas atmosphere is used, migration is suppressed if the pressure is high. Thus, it is preferable to set the atmosphere to a pressure at which migration occurs.

The etching in step ST3 may be performed by using a gas capable of etching silicon. By this etching, for example, as illustrated in FIG. 5, the amorphous silicon portion 12a, fine crystal nuclei 13a, and the like (see FIG. 4) remaining after the annealing in step ST2 and hindering the increase in grain size of the crystal grains are removed. As a result, crystal nuclei suitable for increasing the grain size remain at a low density.

In this case, it is preferable to use an etching gas that is capable of etching with good controllability to remove only the amorphous silicon portion and fine crystal nuclei that are easily etched and to leave crystal nuclei that are capable of growing to a large grain size. That is, when the etching action is too strong, all the crystal nuclei are also etched, so it is preferable to use an etching gas capable of etching with good controllability such that amorphous silicon, which is easily etched, is removed, and only fine crystals disappear from crystalline silicon. From this point of view, it is preferable to use Cl₂ gas as the etching gas. Other etching gases capable of etching with good controllability may be, for example, HBr, F₂, ClF₃, HF, and NF₃. The temperature for the etching in step ST3 may be appropriately set depending on the etching gas, and is preferably 200 to 500 degrees C. when the etching gas is Cl₂ gas.

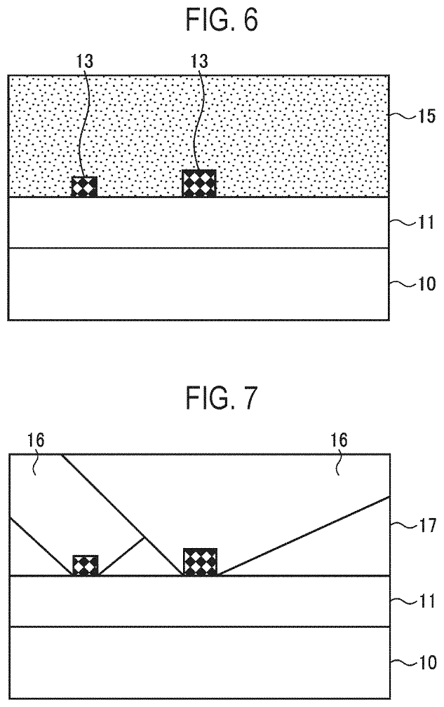

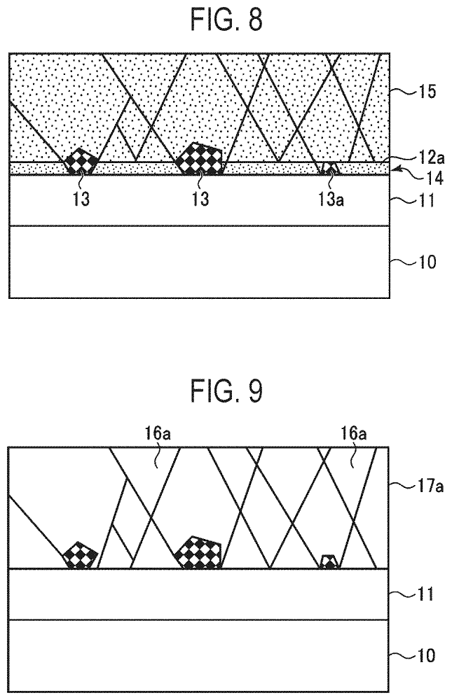

In step ST4, for example, as illustrated in FIG. 6, a second amorphous silicon film 15 is formed on the crystal nuclei 13 remaining after the etching. The second amorphous silicon film 15 is for growing crystal nuclei, and is formed by the CVD method using the Si source gas, like the first amorphous silicon film 12. The conditions at that time may be the same as the conditions at the time of forming the first amorphous silicon film 12.

The film thickness of the second amorphous silicon film 15 is appropriately set depending on the thickness of crystalline silicon to be formed, and may be in the range of 1 to 500 nm (e.g., 30 nm).

In step ST5, by performing a second annealing on the substrate on which the second amorphous silicon film 15 has been formed, the crystal nuclei 13 illustrated in FIG. 6 are grown by using the second amorphous silicon film 15. This makes it possible to form a crystalline silicon film having a large grain size. Crystal growth of the crystal nuclei 13 in this case may be implemented by solid-phase epitaxial growth. As a result, as illustrated in FIG. 7, a crystalline silicon film 17 having silicon crystal grains 16 with a larger grain size is formed.

The second annealing may be performed by a heat treatment, and the temperature at that time is preferably a temperature at which the crystal nuclei 13 are capable of being grown by solid-phase epitaxial growth, and is preferably close to an upper limit of a temperature at which the second amorphous silicon film is capable of maintaining an amorphous state. If the temperature of the second annealing is too high, new crystal nuclei are precipitated, hindering epitaxial growth and making it difficult to obtain large crystal grains. From this point of view, the temperature of the second annealing varies depending on the conditions for forming the second amorphous silicon film 15, but is preferably in the range of 400 to 800 degrees C., typically about 600 degrees C.

When the conditions for forming the first amorphous silicon film 12 and the conditions for forming the second amorphous silicon film 15 are the same, the second annealing temperature is preferably lower than the first annealing temperature.

The atmosphere when performing the second annealing in step ST5 may be a vacuum atmosphere, an H₂ gas atmosphere, or an inert gas atmosphere. However, in the case of the vacuum atmosphere, migration may occur in the second amorphous silicon film 15 and the surface property of the crystalline silicon film may deteriorate. Thus, the H₂ atmosphere or the inert gas atmosphere is preferable. At this time, the pressure at the time of the second annealing is preferably in the range of 0.1 to 100 Torr (13 to 13,000 Pa).

In this embodiment, a crystalline silicon film having a large grain size may be formed by performing steps ST1 to ST5 as described above.

A technique for crystallizing an amorphous silicon film by annealing has been conventionally known, and attempts have been made to increase the grain size by adjusting the conditions. However, the crystal grain size of the obtained crystalline silicon film is about 3 μm, and further increase in grain size is desired. For example, the technique of laminating two layers of amorphous silicon films and then crystallizing the films as in the above-described Patent Document 1 is a technique that is capable of achieving a large grain size, but is still insufficient.

A promising technology for increasing the grain size may be, for example, a heteroepitaxial growth technique, in which after forming an amorphous film, annealing is performed to generate crystal nuclei, then an amorphous film is formed again and grown by solid-phase epitaxial growth. This technique is used for, for example, III-V semiconductors such as GaN and AN. In order to apply this technique to form silicon crystals having a large grain size, silicon crystal nuclei or an underlayer necessary for solid-phase growth are important. However, the crystal nuclei 13 generated by annealing the amorphous silicon film have irregular grain sizes, fine crystal nuclei are present, and amorphous silicon portions having natural nuclei also remain after annealing. Since an amorphous portion having fine crystal nuclei and natural nuclei of silicon also serves as starting points for solid-phase epitaxial growth, the density of crystal nuclei increases, which is disadvantageous in increasing the grain size. The amorphous portion does not grow sufficiently even by solid-phase epitaxial growth, and hinders the increase of grain size of silicon. Moreover, in such a state, the density of crystal nuclei becomes high, which is disadvantageous in increasing the grain size. Although the distance between crystal nuclei can be widened by causing migration in silicon, the problem of the presence of the amorphous portion having fine crystal nuclei and natural nuclei, which hinders the increase of grain size, is not sufficiently resolved.

Specifically, when the second amorphous silicon film 15 is formed and grown by solid-phase epitaxial growth in the state in which the fine crystal grains 13a and the amorphous portion 12a are present as illustrated in FIG. 4, the amorphous portion 12a and the fine crystal grains 13a are also used as starting points for solid-phase epitaxial growth. Therefore, as illustrated in FIG. 9, a crystalline silicon film 17a having small crystal grains 16a is formed.

Therefore, in this embodiment, in addition to the heteroepitaxial growth technique, etching is performed after generating crystal nuclei by performing the first annealing on the first amorphous silicon film and before forming the second amorphous silicon film. This makes it possible to selectively remove the amorphous portion and fine crystal nuclei remaining after annealing. That is, since amorphous silicon is more easily etched than crystalline silicon, the amorphous silicon portion is preferentially etched, and only fine crystal nuclei disappear from the crystalline silicon, so crystal nuclei having a certain level of size remain at relatively large intervals. Therefore, when crystal nuclei are grown by solid-phase epitaxial growth by using the second amorphous silicon film, the crystal nuclei are capable of being sufficiently grown, which makes it possible to obtain silicon crystals having a larger grain size than conventional ones.

As an established technique for forming silicon crystals having a large grain size, there is a metal-induced lateral crystallization (MILC) method using a Ni catalyst. However, this technique requires a metal removal step, and is not realistic for application to a semiconductor device manufacturing process. In this embodiment, since no metal is used, the metal removal step is unnecessary.

An experimental example in which the effect of the first embodiment was actually confirmed will be described. First, for comparison, crystalline silicon was formed by using a heteroepitaxial growth technique and a solid-phase epitaxial growth technique without using etching (Sequence 1). Specifically, a first amorphous silicon film (5 nm) was formed on a substrate by CVD by using Si₂H₆ gas at 425 degrees C., a first annealing was performed at 900 degrees C. to generate crystal nuclei, subsequently a second amorphous silicon film (30 nm) was formed, and then a second annealing was performed at 600 degrees C. to form a crystalline silicon film. The average crystal grain size was measured by an EBSD analysis of the obtained crystalline silicon film. The average crystal grain size was obtained by weighted average based on an area ratio in a field of view of 6 μm×6 μm. As a result, the average crystal grain size was 0.7 μm.

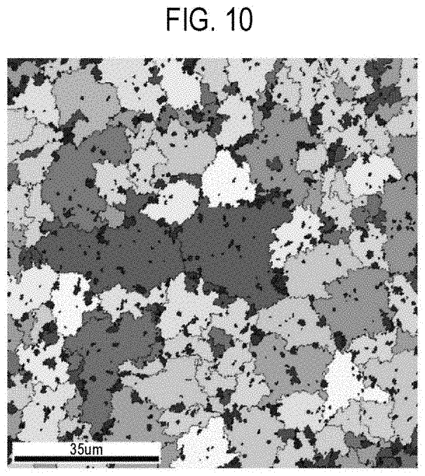

Next, based on this embodiment, crystalline silicon was formed by using a heteroepitaxial growth technique, etching, and a solid-phase epitaxial growth technique (Sequence 2). Specifically, a first amorphous silicon film was formed in the same manner as in Sequence 1, crystal nuclei were generated by performing the first annealing by a heat treatment, then etching was performed with Cl₂ gas, and then crystalline silicon was formed by performing the formation of the second amorphous silicon film and the second annealing in the same manner as in Sequence 1. From the EBSD analysis of the obtained crystalline silicon film, the average crystal grain size was measured in the same manner as in Sequence 1. As a result, in the field of view of 6 μm×6 μm, almost the entire surface was a single crystal (grain size of 6 μm or more), which was much larger than the conventional limit of 3 μm. In addition, the state of crystal grains in a wider field of view of 100 μm×100 μm for Sequence 2 was as shown in the EBSD analysis image of FIG. 10. Similarly, as a result of obtaining the average crystal grain size, the average crystal grain size was a larger value of 12.4 μm.

### Second Embodiment

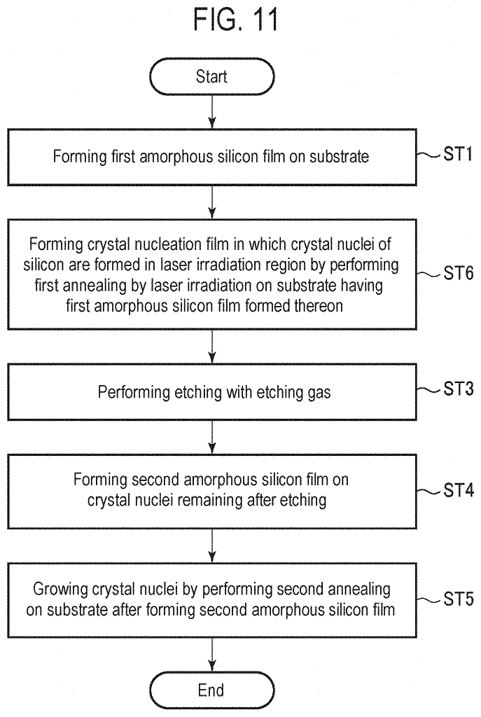

Next, a second embodiment of the crystalline silicon film forming method will be described. FIG. 11 is a flowchart illustrating the second embodiment of the crystalline silicon film forming method.

In this embodiment, after forming a first amorphous silicon film in step ST1 as in the first embodiment, instead of step ST2 in the first embodiment, step ST6 is performed in which the first annealing is performed by laser irradiation to form a crystal nucleation film in which crystal nuclei of silicon are formed in the laser irradiation region. Thereafter, as in the first embodiment, the etching in step ST3, the formation of a second amorphous silicon film in step ST4, and the second annealing in step ST5 are performed to form a crystalline silicon film.

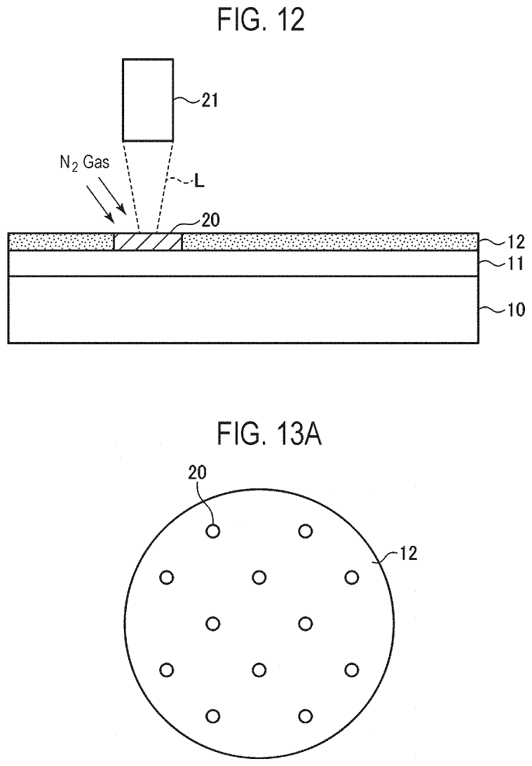

As illustrated in FIG. 12, in the first annealing by a laser in step ST6, the first amorphous silicon film 12 is selectively irradiated with a laser L from a laser irradiator 21 to form an irradiation region 20 by the laser L. It is preferable that the laser irradiation portion be held in an inert gas atmosphere of N₂ gas or the like. Since the laser is able to impart energy only to the irradiation portion with good controllability, only the irradiation region 20 by the laser L of the first amorphous silicon film 12 is annealed. At this time, the portion of the first amorphous silicon film 12 that is not irradiated with the laser L remains as it is in the amorphous state.

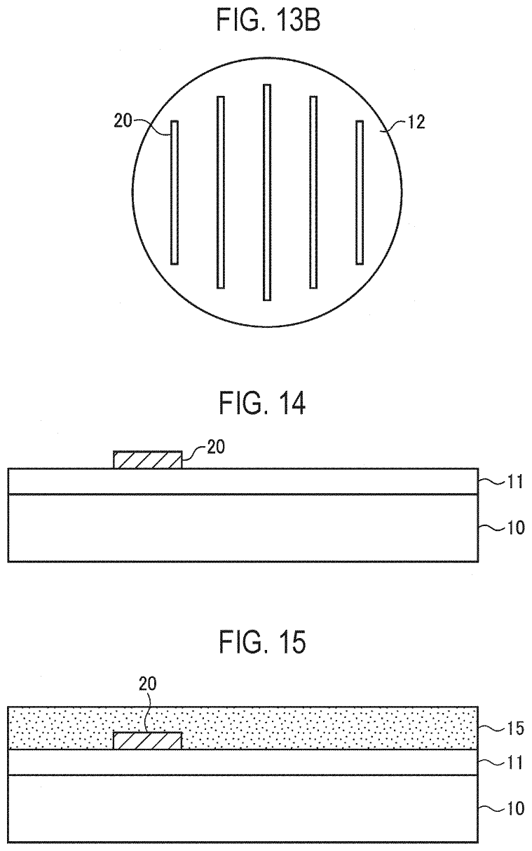

The irradiation region 20 by the laser L is selectively formed on a predetermined portion of the first amorphous silicon film 12 by scanning the laser L as necessary. Then, a crystal nucleation film 14 in which crystal nuclei 13 are generated as illustrated in FIG. 4 is formed in the irradiation region 20 on the first amorphous silicon film 12. As irradiation regions 20 formed in the first amorphous silicon film 12, for example, spot-shaped ones as illustrated in FIG. 13A and line-shaped ones as illustrated FIG. 13B are exemplified. As the laser, a laser having a high absorbability to an amorphous silicon film is preferable, and from such a point of view, one having a wavelength of 100 to 500 nm is preferable. Examples of such a wavelength laser may include, for example, an excimer laser having a wavelength of 193 nm and a UV laser having a wavelength of 355 nm.

The etching in step ST3 is performed in the same manner as in the first embodiment, and as a result of this etching, a portion other than the irradiation region 20 in the first amorphous silicon film 12 and the amorphous portion 12a and the fine crystal nuclei 13a in the crystal nucleation film 14 formed in the irradiation region 20 are removed by etching (for the sake of convenience, FIG. 14 illustrates the state in which the irradiation region 20 remains). Then, the irradiation region 20 is in the state in which the crystal nuclei 13 remain, as in FIG. 5 of the first embodiment.

The formation of the second amorphous silicon film 15 in step ST4 is also performed in the same manner as in the first embodiment, so a second amorphous silicon film 15 is formed on the entire surface including the irradiation region 20 (crystal nuclei 13) in the substrate, as illustrated in FIG. 15.

The second annealing in step ST5 is also performed in the same manner as in the first embodiment, crystal nuclei 13 are grown by using the second amorphous silicon film 15, so a crystalline silicon film 17 is formed over the entire surface of the substrate, as illustrated in FIG. 16. In this embodiment as well, as in the first embodiment, crystal nuclei 13 grow in the crystalline silicon film 17, so silicon crystal grains having an increased size are formed.

In this embodiment, by performing the first annealing with the laser, it is possible to locally apply a large amount of energy, so it is possible to obtain relatively large crystal nuclei in a short time without causing migration. In addition, by using the laser for the first annealing, as illustrated in FIG. 12, it is possible to selectively form the irradiation region 20 by the laser L in the first amorphous silicon film 12, so it is possible to anneal only the irradiation region 20 with good controllability. This enables selective nucleation for the first amorphous silicon film 12 on the substrate. By selectively forming irradiation regions 20 in a desired shape and distribution, for example, in a spot shape and a line shape as illustrated in FIGS. 13A and 13B, it is possible to control nuclear density. That is, by selectively forming the irradiation regions 20 in the first amorphous silicon film 12, the crystal nuclei 13 are not formed in regions other than the irradiation regions 20 in the first amorphous silicon film 12. Thus, it is possible to reduce the nuclear density with respect to the entire first amorphous silicon film 12. By controlling the shape and distribution of the irradiation regions 20, it is possible to control the nuclear density to a desired low density. By reducing the nuclear density in this way, after the second annealing, the crystal nuclei 13 are also capable of growing outside the irradiation regions 20 in the first amorphous silicon film 12, so it is possible to form crystalline silicon having a larger grain size.

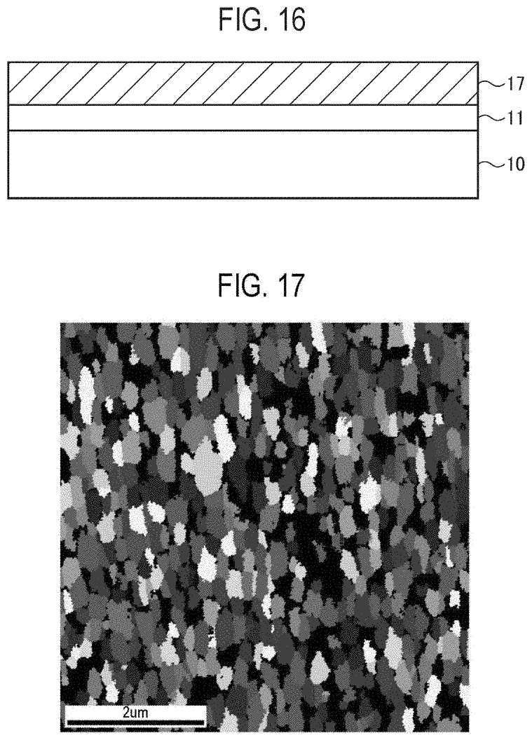

An experimental example in which the effect of the second embodiment was actually confirmed will be described. Here, a first amorphous silicon film (5 nm) was formed on the substrate by CVD at 425 degrees C. by using Si₂H₆ gas, and crystal nuclei were selectively generated by performing the first annealing with a UV laser. The UV laser had a power of 3 W, a defocus amount of 16 mm, a scan speed of 1,000 mm/sec, and a frequency of 30 kHz, and irradiation was performed in a line shape so that the width of a laser irradiation mark was 0.2 mm. As a result of observing the state after the first annealing, it was confirmed that crystal nuclei were formed in the laser irradiation region, while the non-laser irradiation region remained amorphous. FIG. 17 is an EBSD analysis image of a laser irradiation region. The EBSD analysis revealed that the average grain size of crystal nuclei was 0.25 μm (0.30 μm as weighted average by area). From this, it may be expected that a silicon crystal film having a large grain size equal to or greater than that of the first embodiment is formed by subsequent etching, the formation of the second amorphous silicon film, and the second annealing.

### Third Embodiment

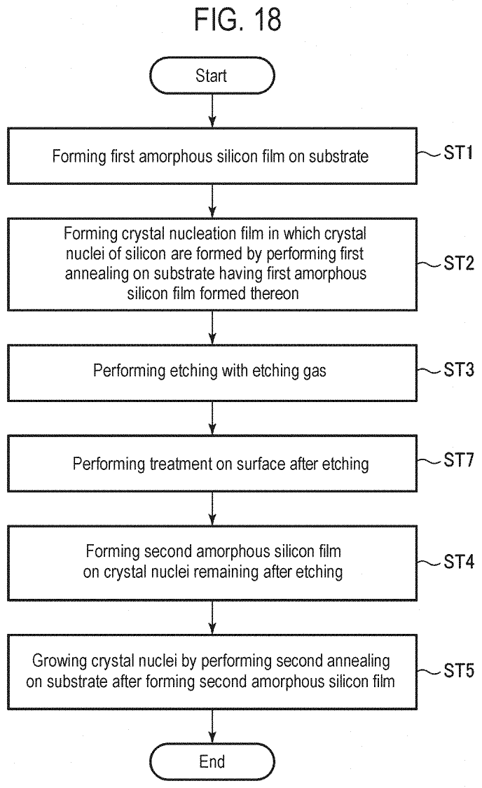

Next, a third embodiment of the crystalline silicon film forming method will be described. FIG. 18 is a flowchart illustrating the third embodiment of the crystalline silicon film forming method.

In this embodiment, as in the first embodiment, after performing the formation of the first amorphous silicon film in step ST1, the first annealing in step ST2, and the etching in step ST3, post-etching surface treatment is performed (step ST7). After the treatment, as in the first embodiment, the formation of the second amorphous silicon film in step ST4 and the second annealing in step ST5 are performed to form a crystalline silicon film.

The treatment in step ST7 may be a process for removing etching gas components remaining on the surface. When the etching of step ST3 is performed, etching gas components remain on the surface of the substrate. For example, Cl₂ gas is known to be directly adsorbed on the silicon surface as chlorine molecules or dissociatively adsorbed as SiCl. If the etching gas components remain on the surface, the gas components become impurities and inhibit the growth of silicon crystal grains.

The treatment of step ST7 may be performed by annealing the substrate after etching. Heating by annealing allows the etching gas components such as Cl₂ gas remaining on the surface to be desorbed from the surface. The annealing temperature at this time is preferably equal to or higher than the temperature at which the etching gas components are desorbed. When Cl₂ gas is used as an etching gas, since the desorption temperature is 600 degrees C., the annealing temperature at the time of removal processing is preferably 600 degrees C. or higher. The atmosphere at the time of annealing may be any of a vacuum atmosphere, an inert gas atmosphere, and an H₂ gas atmosphere.

In this way, by removing the etching gas components remaining on the surface by the treatment, high-quality crystal nuclei may be formed, and the growth of crystal grains is not hindered, which makes it possible to further increase the crystal grains.

In this embodiment, the first annealing by laser irradiation in step ST6 of the second embodiment may be performed instead of the first annealing in step ST2.

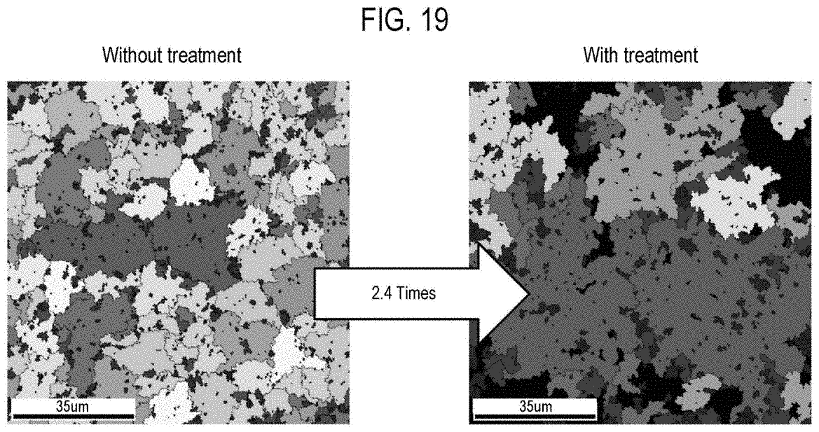

An experimental example in which the effect of the third embodiment was actually confirmed will be described. Here, a first amorphous silicon film was formed under the same conditions as in Sequence 2 in the experimental example of the first embodiment, crystal nuclei were generated by performing the first annealing, and Cl₂ gas remaining on the surface was removed by performing annealing as treatment after performing etching by using Cl₂ gas. Thereafter, crystalline silicon was formed by performing the formation of the second amorphous silicon film and the second annealing in the same manner as in Sequence 2. As the treatment, annealing was performed at 900 degrees C. for 10 minutes in a vacuum atmosphere. The result of comparing the state of the crystal grains in a wide field of view of 100 μm×100 μm in this experimental example with that in Sequence 2 in the experimental example of the first embodiment was as shown in the EBSD analysis images of FIG. 19, and it was confirmed that the crystal grains were further increased according to this embodiment. In addition, the average crystal grain size in the wide field of view of 100 μm×100 μm in the EBSD analysis of the obtained crystalline silicon film was measured. The average crystal grain size was obtained by weighted average based on the area ratio, as in the experimental example of the first embodiment. As a result, the average crystal grain size of the crystalline silicon film in this experimental example was 29.2 μm, which is about 2.4 times larger than the 12.4 μm of Sequence 2 in the experimental example of the first embodiment. While the maximum grain size was 25 μm in Sequence 2 in the experimental example of the first embodiment, the maximum grain size in this experimental example was approximately doubled to 49 μm.

### <Processing Apparatus>

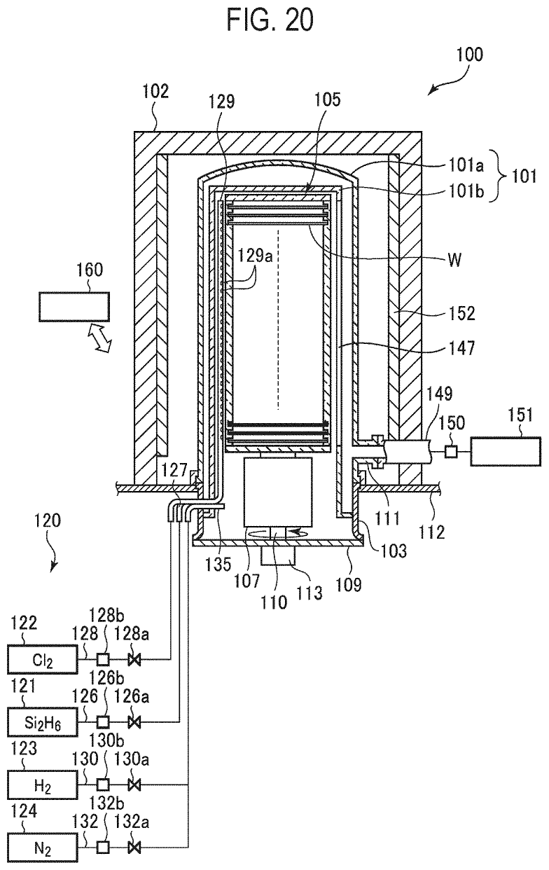

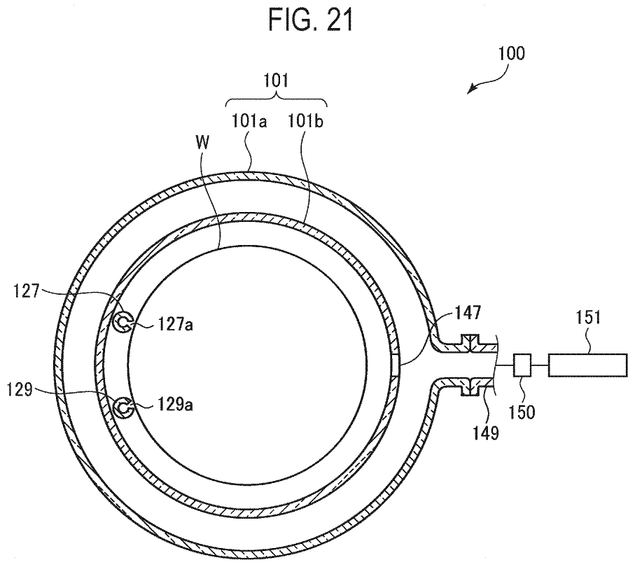

Next, an example of a processing apparatus capable of implementing the crystalline silicon film forming method of the above-described embodiments will be described. FIG. 20 is a vertical cross-sectional view illustrating an example of the processing apparatus, and FIG. 21 is a horizontal cross-sectional view thereof.

The processing apparatus 100 of this example is configured as an apparatus that performs all the steps of the method of the first embodiment. The processing apparatus 100 of this example is constituted as a hot wall-type vertical batch-type heat treatment apparatus and includes a processing container 101 configured as a reaction tube having a double tube structure including an outer tube 101a and an inner tube 101b and having a ceiling. The entire processing container 101 is made of, for example, quartz. In the inner tube 101b of the processing container 101, a wafer boat 105 made of quartz, in which 50 to 150 wafers W, which are semiconductor substrates, are mounted in multiple stages is disposed. As each of the wafers W, for example, one obtained by forming a SiO₂ film on a silicon base body is used. A substantially cylindrical main body 102 having an opening at the lower surface side thereof is provided outside the processing container 101, and a heating mechanism 152 having a heater in the circumferential direction is provided on the inner wall surface of the main body 102. The main body 102 is supported by a base plate 112.

A cylindrical manifold 103 made of, for example, stainless steel is connected to the lower end opening of the outer tube 101a of the processing container 101 via a seal member (not illustrated) such as an O-ring.

The manifold 103 supports the outer tube 101a of the processing container 101, and from the lower side of the manifold 103, the wafer boat 105 is inserted into the inner tube 101b of the processing container 101. The bottom portion of the manifold 103 is closed by a lid 109.

The wafer boat 105 is mounted on a heat insulating cylinder 107 made of quartz, a rotary shaft 110 is installed in the heat insulating cylinder 107 through the lid 109, and the rotary shaft 110 is configured to be rotatable by a rotary drive mechanism 113 such as a motor. Thus, the wafer boat 105 is configured to be rotatable via the heat insulating cylinder 107 by the rotary drive mechanism 113. The heat insulating cylinder 107 may be fixedly provided on the lid 109 side, and the wafers W may be processed without rotating the wafer boat 105.

The processing apparatus 100 includes a gas supply mechanism 120 configured to supply various gases. The gas supply mechanism 120 includes a Si₂H₆ gas source 121 configured to supply Si₂H₆ gas as an Si source gas, a Cl₂ gas source 122 configured to supply Cl₂ gas as an etching gas, a H₂ gas source 123, and a N₂ gas source 124 configured to supply N₂ gas as an inert gas. As the Si source gas and the etching gas, other gases described above may be used. In addition, as the inert gas, a rare gas such as Ar gas may be used instead of the N₂ gas.

A pipe 126 is connected to the Si₂H₆ gas source 121, and a gas diffusion nozzle 127 made of quartz is connected to the pipe 126, in which the gas diffusion nozzle 127 passes through sidewalls of the manifold 103 and the inner tube 101b of the processing container 101 and is bent upward in the inner tube 101b to extend vertically. A pipe 128 is connected to the Cl₂ gas source 122, and a gas distribution nozzle 129 made of quartz is connected to the pipe 128, in which the gas distribution nozzle 129 passes through sidewalls of the manifold 103 and the inner tube 101b and is bent upward in the inner tube 101b to extend vertically. A pipe 130 is connected to the H₂ gas source 123, and a linear gas nozzle 135 made of quartz is connected to the pipe 130, in which the gas nozzle 135 passes through sidewalls of the manifold 103 and the inner tube 101b and reaches the inside of the processing container 101. A pipe 132 is connected to the N₂ gas source 124, and the pipe 132 is connected to the pipe 130. The gas nozzle 135 made of quartz may be a gas distribution nozzle made of quartz and bent upward in the inner tube 101b to extend vertically.

The pipe 126 is provided with an opening/closing valve 126a and a flow rate controller 126b such as a mass flow controller on the upstream side of the opening/closing valve 126a. Similarly, the pipes 128, 130, and 132 are also provided with opening/closing valves 128a, 130a, and 132a and flow rate controllers 128b, 130b, and 132b, respectively.

In the vertical portions of the gas diffusion nozzles 127 and 129, multiple gas ejection holes 127a and 129a are formed at predetermined intervals corresponding to the respective wafers W over a vertical length corresponding to the wafer support range of the wafer boat 105 (FIG. 20 illustrates only the gas ejection holes 129a). Thus, gases may be ejected substantially uniformly from respective gas ejection holes 127a and 129a toward the processing container 101 in the horizontal direction.

An exhaust port 147 for evacuating the interior of the processing container 101 is provided in a portion of the inner tube 101b of the processing container 101 opposite to the arrangement positions of the gas diffusion nozzles 127 and 129. The exhaust port 147 is elongated vertically so as to correspond to the wafer boat 105. An exhaust port 111 is formed in the outer tube 101a of the processing container 101 in the vicinity of the exhaust port 147, and an exhaust pipe 149 configured to evacuate the processing container 101 is connected to the exhaust port 111. A pressure control valve 150 configured to control the pressure inside the processing container 101 and an exhaust device 151 including a vacuum pump or the like are connected to the exhaust pipe 149, and the interior of the processing container 101 is evacuated by the exhaust device 151 through the exhaust pipe 149.

The processing container 101 and the wafers W inside the processing container 101 are heated to a predetermined temperature by supplying power to the heating mechanism 152 inside the above-mentioned main body 102.

The processing apparatus 100 has a controller 160. The controller 160 controls each component of the processing apparatus 100 such as valves, mass flow controllers as flow rate controllers, and drive mechanisms such as a lifting mechanism, or a heating mechanism 152. The controller 160 has a main controller having a CPU, an input device, an output device, a display device, and a storage device. In the storage device, a non-transitory computer readable storage medium that stores a program for controlling a process to be executed in the processing apparatus 100, that is, processing recipes is set, and the main controller reads a predetermined processing recipe stored in the storage medium and performs control such that a predetermined process is performed by the processing apparatus 100 based on the processing recipe.

Next, an example of the processing operation of the processing apparatus 100 will be described. The processing in the processing apparatus 100 is performed as follows based on the processing recipe stored in the storage medium in the controller 160.

First, a plurality of wafers W (e.g., 50 to 150 wafers W) is placed in the wafer boat 105, and the wafer boat 105 is inserted into the processing container 101 in the processing apparatus 100 from the lower side, so that the plurality of wafers W is accommodated in the inner tube 101b of the processing container 101. Next, by closing the lower end opening of the manifold 103 with the lid 109, the space inside the processing container 101 is sealed.

After the interior of the processing container 101 is evacuated by the exhaust device 151, N₂ gas, which is an inert gas, is supplied into the processing container 101 from the N₂ gas source 124 through the pipes 132 and 130 and the gas nozzle 135 to regulate the internal pressure of the processing container 101, and the temperature in the processing container 101 (the temperature of the wafers W) is stabilized by the heating mechanism 152. While supplying the N₂ gas, Si₂H₆ gas is supplied from the Si₂H₆ gas source 121 through the pipe 126 to the gas diffusion nozzle 127, and ejected from the gas ejection holes 127a, thereby forming a first amorphous silicon film on the surface of each wafer W by CVD. At this time, the temperature of the wafers W is set to 350 to 500 degrees C. (e.g., 425 degrees C.), and the pressure is set to 0.1 to 10 Torr (13 to 1,300 Pa).

After the formation of the first amorphous silicon film is completed, the supply of the Si₂H₆ gas is stopped and the interior of the processing container 101 is purged with N₂ gas. Thereafter, the interior of the processing container 101 is evacuated to a vacuum atmosphere, the temperature of the wafers W is raised by the heating mechanism 152 to a temperature (e.g., 900 degrees C.) higher than the temperature for forming the first amorphous silicon film, and a first annealing is performed on the wafers W. As a result, crystal nuclei are generated from the first amorphous silicon film, and a crystal nucleation film is formed.

Thereafter, the temperature of the wafers W is set to 200 to 500 degrees C., Cl₂ gas is supplied as an etching gas from the Cl₂ gas source 122 to the gas diffusion nozzle 129 through the pipe 128 while supplying N₂ gas, and etching is performed by ejecting the Cl₂ gas from the gas ejection holes 129a.

After the etching is completed, the supply of the Cl₂ gas is stopped, and the interior of the processing container 101 is purged with N₂ gas. Thereafter, the temperature and pressure are set to be the same as in the formation of the first amorphous silicon film, and in the same manner as in the formation of the first amorphous silicon film, Si₂H₆ gas is supplied to form a second amorphous silicon film on the etched crystal nucleation film of each of the wafers W.

After the formation of the second amorphous silicon film is completed, the supply of the Si₂H₆ gas is stopped and the interior of the processing container 101 is purged with N₂ gas. Thereafter, after the interior of the processing container 101 is evacuated to a vacuum atmosphere, H₂ gas is supplied from the H₂ gas source 123 into the processing container 101 through the pipe 130 and the gas nozzle 135 to form a H₂ atmosphere inside the processing container 101, and the second annealing is performed. At this time, the temperature of the wafers W is set to around the crystallization temperature of amorphous silicon (e.g., 600 degrees C.), and the pressure is set to 0.1 to 100 Torr (13 to 13,000 Pa).

As a result, the crystal nuclei generated on the surface of the first amorphous silicon film are grown by the first annealing, and a crystalline silicon film having a large grain size is obtained.

After the etching and before the formation of the second amorphous silicon film, the interior of the processing container 101 may be evacuated, the temperature of the wafers W may be raised to 600 degrees C. or higher by the heating mechanism 152, and annealing for removing the etching gas components from the surfaces of the wafers W may be performed. This may further increase the crystal grain size of the crystalline silicon film.

### OTHER APPLICATIONS

Although embodiments have been described above, it should be considered that the embodiments disclosed herein are exemplary in all respects and are not restrictive. The above embodiments may be omitted, replaced, or modified in various forms without departing from the scope and gist of the appended claims.

For example, an impurity-containing gas may be used together with the Si source gas when forming the first amorphous silicon film and the second amorphous silicon film. Examples of impurities include arsenic (As), boron (B), and phosphorus (P), and as the impurity-containing gas, arsine (AsH₃), diborane (B₂H₆), boron trichloride (BCl₃), or phosphine (PH₃) may be used.

In addition, in the above-described embodiments, a vertical batch type apparatus is used as a processing apparatus, but without being limited thereto, various other processing apparatuses such as a horizontal batch-type apparatus and a single wafer-type apparatus may also be used. Moreover, although an example in which all the steps are performed in a single processing apparatus has been illustrated, some of the steps (e.g., etching and annealing) may be performed in another apparatus. For example, when executing the method of the second embodiment, only the step of performing the first annealing by laser irradiation may be performed in a laser irradiation unit, and the other steps may be performed in a single processing apparatus such as a vertical batch-type apparatus.

In addition, the above-described embodiments have been described by taking a semiconductor substrate (wafer) as an example of the substrate, but without being limited thereto, the substrate may be another substrate such as a glass substrate or a ceramic substrate.

According to the present disclosure, it is possible to form crystalline silicon having a larger grain size.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a crystalline silicon film, the method comprising:
forming a first amorphous silicon film on a substrate;
forming a crystal nucleation film in which crystal nuclei of silicon are formed by performing a first annealing on the substrate having the first amorphous silicon film formed thereon;
performing etching with an etching gas;
forming a second amorphous silicon film on the crystal nuclei remaining after the etching; and
forming the crystalline silicon film by performing a second annealing on the substrate after the forming of the second amorphous silicon film to grow the crystal nuclei.

2. The method of claim 1, wherein the substrate includes an underlayer film formed on a base body, and the first amorphous silicon film is formed on the underlayer film.

3. The method of claim 2, wherein the underlayer film is an insulating film.

4. The method of claim 1, wherein the first amorphous silicon film has a thickness of 15 nm or less.

5. The method of claim 1, wherein the first annealing is performed by a heat treatment.

6. The method of claim 5, wherein the first annealing is performed at a temperature higher than a temperature at which the first amorphous silicon film is formed.

7. The method of claim 6, wherein the first annealing is performed at a temperature at which migration occurs in the first amorphous silicon film.

8. The method of claim 7, wherein the first annealing is performed at a temperature of 800 degrees C. or higher.

9. The method of claim 5, wherein the first annealing is performed in a vacuum atmosphere.

10. The method of claim 5, wherein the first annealing is performed in a H₂ gas atmosphere.

11. The method of claim 1, wherein the first annealing is performed by laser irradiation to form the crystal nucleation film in a laser irradiation region.

12. The method of claim 11, wherein the irradiation region is selectively formed in the first amorphous silicon film.

13. The method of claim 1, wherein the etching is performed by supplying an etching gas capable of etching silicon.

14. The method of claim 13, wherein, in the performing the etching, Cl₂ gas is used as the etching gas.

15. The method of claim 13, wherein the etching is performed at a temperature of 200 to 500 degrees C.

16. The method of claim 1, wherein the second amorphous silicon film has a thickness in a range of 1 to 500 nm.

17. The method of claim 1, wherein the second annealing grows the crystal nuclei by solid phase epitaxial growth.

18. The method of claim 17, wherein the second annealing is performed at a temperature close to an upper limit of a temperature at which the second amorphous silicon film is capable of maintaining an amorphous state.

19. The method of claim 18, wherein the second annealing is performed at a temperature in a range of 400 to 800 degrees C.

20. The method of claim 17, wherein the second annealing is performed in a H₂ gas atmosphere or an inert gas atmosphere.

21. The method of claim 1, further comprising:
performing treatment of an etched surface after the etching.

22. The method of claim 21, wherein, in the performing the treatment, an etching gas component remaining on the surface after the etching is removed.

23. The method of claim 22, wherein, in the performing the treatment, the etching gas component adsorbed on the surface is desorbed by annealing.

24. An apparatus for forming a crystalline silicon film, the apparatus comprising:
a processing container configured to accommodate a substrate therein;
a gas supply configured to supply a gas into the processing container; and
a heating mechanism configured to heat the substrate;
an exhaust mechanism configured to evacuate an interior of the processing container; and
a controller,
wherein the controller is configured to control the gas supply, the heating mechanism, and the exhaust mechanism to perform:
forming a first amorphous silicon film on the substrate by supplying a silicon source gas into the processing container;
forming a crystal nucleation film in which crystal nuclei of silicon are formed by performing a first annealing on the substrate having the first amorphous silicon film formed thereon;
performing etching by supplying an etching gas to the processing container;
forming a second amorphous silicon film on the crystal nuclei remaining after the etching by supplying a silicon source gas into the processing container; and
forming the crystalline silicon film by performing a second annealing on the substrate after the forming of the second amorphous silicon film to grow the crystal nuclei.
